(19) United States
(12) Patent Application Publication
(10) Pub. No.: US 2012/0199470 A1
(43) Pub. Date: Aug. 9, 2012

(54) MTJ FILM AND METHOD FOR MANUFACTURING THE SAME

(75) Inventors: Kaoru MORI, Kanagawa (JP); Eiji KARIYADA, Kanagawa (JP); Katsumi SUEMITSU, Kanagawa (JP); Norikazu OHSHIMA, Kanagawa (JP)

(73) Assignee: RENESAS ELECTRONICS CORPORATION, Kawasaki-shi (JP)

(21) Appl. No.: 13/364,740

(22) Filed: Feb. 2, 2012

(30) Foreign Application Priority Data
Feb. 7, 2011 (JP) 2011-024227

(51) Int. Cl. C23C 14/34; C23C 14/06

(52) U.S. Cl. 204/192.2

(57) ABSTRACT

A method for manufacturing an MTJ film includes forming a first ferromagnetic layer; forming a tunnel barrier layer over the first ferromagnetic layer; and forming a second ferromagnetic layer over the tunnel barrier layer. The first ferromagnetic layer is a Co/Ni stacked film having perpendicular magnetic anisotropy. The step for forming a tunnel barrier layer includes repeating unit film formation treatment n times (n is an integer of 2 or more). The unit film formation treatment includes the steps of: depositing an Mg film by a sputtering method; and oxidizing the deposited Mg film. A film thickness of the deposited Mg film in the first unit film formation treatment is 0.3 nm or more and 0.5 nm or less. A film thickness of the deposited Mg film in the second unit film formation treatment or later is 0.1 nm or more and 0.45 nm or less.

### CROSS-REFERENCE TO RELATED APPLICATIONS

The disclosure of Japanese Patent Application No. 2011-24227 filed on Feb. 7, 2011 including the specification, drawings and abstract is incorporated herein by reference in its entirety.

### BACKGROUND

The present invention relates to a method for manufacturing an MTJ (Magnetic Tunnel Junction) film. In particular, the present invention relates to a method for manufacturing an MTJ film in which a tunnel barrier layer is formed by a multi-step oxidation method.

A magnetic random access memory (MRAM) is a promising nonvolatile memory from the viewpoint of high integration and high operation speed. In MRAM, a magnetic resistance element showing a magnetic resistance effect is used as a memory cell. As a typical magnetic resistance element, an MTJ (Magnetic Tunnel Junction) in which a tunnel barrier layer is sandwiched between two ferromagnetic layers has been known.

FIG. 1 schematically shows a structure of a typical MTJ film. The typical MTJ film includes a stacked layer structure in which a first ferromagnetic layer 110, a tunnel barrier layer 120 and a second ferromagnetic layer 130 are stacked in order. The tunnel barrier layer 120 is a thin insulating layer having a film thickness of 1-2 nm, and a material thereof is oxides of Al and Mg. Each of the first ferromagnetic layer 110 and the second ferromagnetic layer 130 has magnetization (in an example of FIG. 1, both are magnetization in a direction in a surface). Here, one of the first ferromagnetic layer 110 and the second ferromagnetic layer 130 is a magnetization fixed layer (a pin layer) in which a magnetization direction is fixed, and the other is a magnetization free layer (a free layer) in which the magnetization direction can invert. When the magnetization direction of the magnetization fixed layer and the magnetization free layer is “antiparallel”, a resistance value of the MTJ is larger than the resistance value in the case that they are “parallel” by the magnetic resistance effect. The MTJ film nonvolatilely stores data by using such a resistance value change. Data is written to the MTJ film by inverting the magnetization direction of the magnetization free layer.

Writing properties and readout properties of the MRAM are determined by film properties of the MTJ. For example, a covering property and film quality of the tunnel barrier layer significantly contribute to the readout properties. Main readout properties include resistance-area product, that is, standardized junction resistance (R×A; R: element resistance, A: junction area), and a ratio of the magnetic resistance (an MR ratio). These R×A and the MR ratio can be obtained by a CIPT (Current In-Plane Tunneling) method. Deterioration in the covering property and the film quality of the tunnel barrier layer leads to decrease in the R×A (short circuit) and decrease in the MR ratio. Therefore, formation of an excellent tunnel barrier layer is desired.

One of the methods for forming the tunnel barrier layer includes RF sputtering using an oxide target (an example: MgO). However, it has been known that uniformity of junction resistance in a wafer surface is not good, when the tunnel barrier layer is formed by RF sputtering. In addition, RF sputtering is not adequate for mass production of the MRAM from the view point of particle generation and target contamination.

A “post-oxidation method” has been known as a method for forming the tunnel barrier layer. According to the post-oxidation method, (1) a metal deposition step of depositing a metal film (an Al film and an Mg film) is deposited by a sputtering method is firstly performed, and then, (2) an oxidation step of oxidizing the deposited metal film by introducing oxygen radical and the like is performed. Thereby, the tunnel barrier layer made of Al₂O₃ or MgO is formed. The post-oxidation method has a feature in which excellent uniformity of junction resistance in a wafer surface is obtained, and is considered as an essential technology for mass production of the MRAM.

A “multi-step oxidation method” is one of the post-oxidation methods and repeats the metal deposition step and the oxidation step described above twice or more. In other words, when one set of the metal deposition step and the oxidation step are defined as “unit film formation treatment”, the unit film formation treatment is repeatedly performed more than once.

Japanese Unexamined Patent Application Publication No. 2000-357829 discloses a technology which relates to the multi-step oxidation method. According to the related technology, a film thickness of the deposited metal film is set to 0.3 nm or more and less than 1 nm in the first unit film formation treatment. A film thickness of the deposited metal film is set to 0.1 nm to 1.5 nm in the second unit film formation treatment or later. It is described that a tunnel barrier layer having an oxidation state without excess and deficiency is formed thereby.

### SUMMARY

Recently, a perpendicular magnetization film having perpendicular magnetic anisotropy has been noticed from the viewpoint of reduction in writing current in current-driven domain wall motion MRAM. One of the most promising perpendicular magnetization film at the present moment is a Co/Ni stacked film in which Co thin films and Ni thin films are alternatively stacked. In order to generate perpendicular magnetic anisotropy in the Co/Ni stacked film, control of crystal orientation using an adequate underlayer is important. The Co/Ni stacked film becomes a microcrystalline film having strong fcc (111) orientation by forming the Co/Ni stacked film over the adequate underlayer. In this case, strong perpendicular magnetic anisotropy can be realized.

Here, the inventors of the present invention have first found the following problem through experiments. The problem is that the readout properties (a R×A and an MR ratio) may deteriorate when an MgO film is formed as a tunnel barrier layer over the Co/Ni stacked film having perpendicular magnetic anisotropy by the post-oxidation method and the multi-step oxidation method described above. For example, a sample of depositing an Mg film having a thickness of 0.7 nm is formed respectively in the first time and the second time unit film formation treatment so as to satisfy a film thickness condition described in Japanese Unexamined Patent Application Publication No. 2000-357829 described above (also refer to FIG. 8B described below). Deterioration in the R×A and the MR ratio is confirmed about this sample (also refer to FIG. 11 and FIG. 12 described below).

Also, the inventors of the present invention have experimentally confirmed that such a problem is specific to the post-oxidation method and the multi-step oxidation method and does not occur in the case of the RF sputtering. More specifically, the problem described above does not occur when an MgO film is formed over the Co/Ni perpendicular magnetization film as a tunnel barrier layer by the RF sputtering using the MgO target.

Form these results, the present inventors of the present invention have considered that the problem described above is caused by “growth of crystal grains”. Mechanism of occurrence of the problem which the inventors of the present invention have considered is described with reference to FIG. 2.

FIG. 2 shows an aspect in which an Mg film having a thickness of about 1-2 nm is deposited over the Co/Ni stacked film having perpendicular magnetic anisotropy. As described above, the Co/Ni stacked film having perpendicular magnetic anisotropy is the microcrystalline film having strong fcc (111) orientation. Such a Co/Ni stacked film having high crystalline orientation is considered to act as foundation to Mg crystal growth and accelerates epitaxial Mg crystal growth. Therefore, growth of Mg crystal grains starts even if the film thickness is about 1-2 nm. As shown in FIG. 2, a part locally having thin film thickness is generated when the Mg crystal grains are grown. In other words, a covering property of the tunnel barrier layer deteriorates.

When the part locally having thin film thickness is generated during the Mg deposition step as described above, a Co/Ni stacked film of lower layer may also be oxidized through the part having thin film thickness in successive oxidation step. This causes decrease in the MR ratio. In addition, the part locally having thin film thickness becomes a leak spot when element diffusion at an interface proceeds by heat treatment. This causes junction short circuit (decrease in the R×A) and decrease in the MR ratio. It can be said that heat resistance of the MTJ film deteriorates because R×A and the MR ratio are decreased by heat treatment (also refer to FIG. 9 and FIG. 10 described below).

As described above, decrease in R×A and the MR ratio is observed in the sample which satisfies a film thickness condition described in Japanese Unexamined Patent Application Publication No. 2000-357829 (each Mg film having a thickness of 0.7 nm is deposited in the first and the second unit film formation treatment) in a similar way. From this result, a similar phenomenon is probably generated even when the film thickness is about 0.7 nm. In other words, readout properties may deteriorate within a range of film thickness defined in Japanese Unexamined Patent Application Publication No. 2000-357829. This is because the “growth of crystal grains” is not recognized in Japanese Unexamined Patent Application Publication No. 2000-357829.

As described above, the readout properties (the R×A and the MR ratio) may deteriorate, when the tunnel barrier layer is formed by the post-oxidation method and the multi-step oxidation method. Here, a ferromagnetic layer of the lower layer is not limited to the Co/Ni stacked film having perpendicular magnetic anisotropy. From the view point of growth of crystal grains, a similar problem is considered to be generated when the tunnel barrier layer is formed over a ferromagnetic layer having high crystal orientation by the post-oxidation method and the multi-step oxidation method. Suppressing deterioration in readout properties is desired when the MTJ film is formed by forming the tunnel barrier layer over a ferromagnetic layer having high crystal orientation.

In an aspect of the present invention, a method for manufacturing an MTJ film is provided. The method for manufacturing includes the steps of forming a first ferromagnetic layer, forming a tunnel barrier layer over the first ferromagnetism layer, and forming a second ferromagnetic layer over the tunnel barrier layer. The first ferromagnetic layer is a Co/Ni stacked film having perpendicular magnetic anisotropy. The step of forming the tunnel barrier layer includes repeating unit film formation treatment n times (n is an integer of 2 or more). The unit film formation treatment includes the steps of depositing an Mg film by a sputtering method, and oxidizing the deposited Mg film. A film thickness of the deposited Mg film in the first unit film formation treatment is 0.3 nm or more and 0.5 nm or less. A film thickness of the deposited Mg film in the second unit film formation treatment or later is 0.1 nm or more and 0.45 nm or less.

In another aspect of the present invention, a method for manufacturing an MTJ film is provided. The method for manufacturing includes the steps of forming a first ferromagnetic layer, forming a tunnel barrier layer over the first ferromagnetic layer, and forming a second ferromagnetic layer over the tunnel barrier layer. The first ferromagnetic layer has a crystal structure having an fcc (111) orientation. The step of forming the tunnel barrier layer includes repeating unit film formation treatment n times (n is an integer of 2 or more). The unit film formation treatment includes the steps of depositing an Mg film by a sputtering method, and oxidizing the deposited Mg film. A film thickness of the deposited Mg film in the first unit film formation treatment is 0.3 nm or more and 0.5 nm or less. A film thickness of the deposited Mg film in the second unit film formation treatment or later is 0.1 nm or more and 0.45 nm or less.

In further other aspect of the present invention, an MTJ film is provided. The MTJ film includes a first ferromagnetic layer, a tunnel barrier layer formed over the first ferromagnetic layer, and a second ferromagnetic layer formed over the tunnel barrier layer. The first ferromagnetic layer is a Co/Ni stacked film having perpendicular magnetic anisotropy. The tunnel barrier layer includes n layers (n is an integer of 2 or more) of MgO films. A film thickness of a first MgO film closest to the first ferromagnetic layer among the n layers of MgO films is 0.2415 nm or more and 0.4025 nm or less. Each film thickness of the n layers of MgO films except the first MgO film is 0.0805 nm or more and 0.36225 nm or less.

According to the aspects of present invention, deterioration in readout properties can be suppressed when the MTJ film is formed by forming the tunnel barrier layer over the ferromagnetic layer having high crystal orientation.

### BRIEF DESCRIPTION OF THE DRAWINGS

FIG. 1 schematically shows a typical MTJ film structure;

FIG. 2 is a view for illustrating the problem to be solved by the present invention;

FIG. 3 is a cross-sectional view showing one example of an MTJ film structure according to an embodiment of the present invention;

FIG. 4 is a cross-sectional view showing another example of an MTJ film structure according to an embodiment of the present invention;

FIG. 5 is a schematic view showing a method for manufacturing the MTJ film according to an embodiment of the present invention;

FIG. 6 is a schematic view showing a modification of the method for manufacturing the MTJ film according to the embodiment of the present invention;

FIG. 7 shows a sample film configuration used in experiments;

FIG. 8A is a schematic view showing Mg film thickness conditions of Sample A;

FIG. 8B is a schematic view showing Mg film thickness conditions of Sample B;

FIG. 8C is a schematic view showing Mg film thickness conditions of Sample C;

FIG. 8D is a schematic view showing Mg film thickness conditions of Sample D;

FIG. 9 is a graph showing annealing temperature dependence of R×As of Sample A;

FIG. 10 is a graph showing annealing temperature dependence of MR ratios of Sample A;

FIG. 11 is a graph showing oxidation time dependence of R×As of each sample;

FIG. 12 is a graph showing oxidation time dependence of MR ratios of each sample;

FIG. 13 is a graph showing Mg film thickness dependence of R×As of each sample; and

FIG. 14 is a graph showing Mg film thickness dependence of MR ratios of each sample.

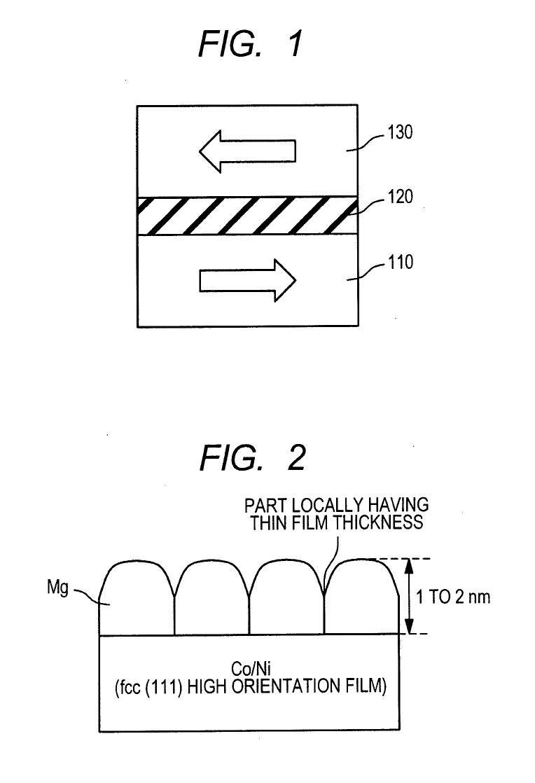

### DETAILED DESCRIPTION

The embodiment of the present invention is described with reference to the accompanying drawings.

### 1. Structure

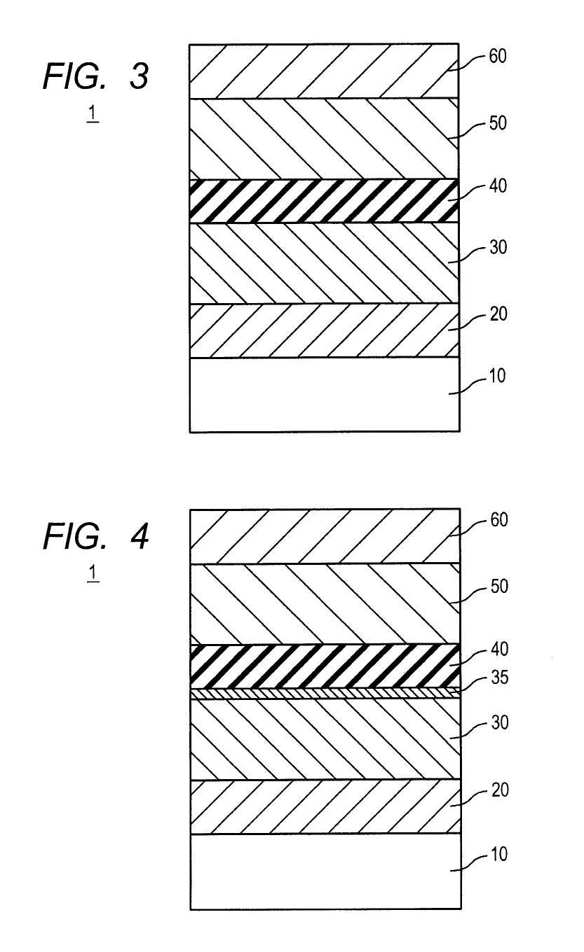

FIG. 3 is a cross-sectional view showing one example of an MTJ film structure according to the embodiment. A underlayer 20 is formed over a substrate 10. A first ferromagnetic layer 30 is formed over the underlayer 20. A tunnel barrier layer 40 is formed over the first ferromagnetic layer 30. A second ferromagnetic layer 50 is formed over the tunnel barrier layer 40. A cap layer 60 is formed over the second ferromagnetic layer 50.

The tunnel barrier layer 40 is sandwiched between the first ferromagnetic layer 30 and the second ferromagnetic layer 50. A magnetic tunnel junction (MTJ) is formed by these first ferromagnetic layer 30, ferromagnetic layer 40 and second ferromagnetic layer 50. In such an MTJ film 1, for example, the first ferromagnetic layer 30 functions as a magnetization free layer or a domain wall motion layer, and the second ferromagnetic layer 50 functions as a magnetization fixed layer.

In the embodiment, the first ferromagnetic layer 30 has high crystal orientation. More specifically, the first ferromagnetic layer 30 has a crystal structure having strong fcc (111) orientation. Typically, the first ferromagnetic layer 30 is a Co/Ni stacked film in which Co thin films and Ni thin films are alternatively stacked. The Co/Ni stacked film having the crystal structure having strong fcc (111) orientation can be formed by adequately selecting the underlayer 20. In this case, the Co/Ni stacked film becomes to have perpendicular magnetic anisotropy (an easy axis of magnetization is in a perpendicular direction to the film surface). In other words, a Co/Ni stacked film having perpendicular magnetic anisotropy is equal to a Co/Ni stacked film having high crystal orientation. Writing current can be reduced by using the Co/Ni stacked film having perpendicular magnetic anisotropy as a domain wall motion layer of a domain wall motion type MRAM. Therefore the use is preferable.

The underlayer 20 is formed by a material so as to realize the first ferromagnetic layer 30 having high crystal orientation as described above. The underlayer 20 may have a stacked structure in which multiple layers are stacked. The preferable underlayer 20 includes Ta/Pt, Co/Pt, NiFeB/Pt, NiFeZr/Pt and NiFeZr/Pt/CoPt.

The tunnel barrier layer 40 is an MgO film having .a film thickness of about 1-2 nm. As described below in detail, the tunnel barrier layer 40 is formed over the first ferromagnetic layer 30 by the multi-step oxidation method.

The second ferromagnetic layer 50 includes any of Co, Ni and Fe or an alloy thereof. The second ferromagnetic layer 50 may have a stacked structure in which multiple layers are stacked. For example, the second ferromagnetic layer is a Co/Pt stacked film in which Co thin films and Pt thin films are alternatively stacked. The second ferromagnetic layer 50 may also have a stacked ferrimagnetic structure.

The cap layer 60 is a layer for preventing transformation of the MTJ film caused by process damage at the time of heat treatment or element shape processing. A material for the cap layer 60 includes Ta and Ru. The cap layer 60 may not be provided.

FIG. 4 is a cross-sectional view showing another example of an MTJ film 1 structure according to the embodiment. As shown in FIG. 4, a thin interface layer 35 may exist between the first ferromagnetic layer 30 and the tunnel barrier layer 40. More specifically, the tunnel barrier layer 40 may not always be formed “directly over” the ferromagnetic layer 30, and may be formed over the first ferromagnetic layer 30 through the thin interface layer 35. The interface layer 35 is, for example, an amorphous CoFeB layer. In this case, increase in the MR ratio of the MTJ film 1 is known.

### 2. Method for Manufacturing

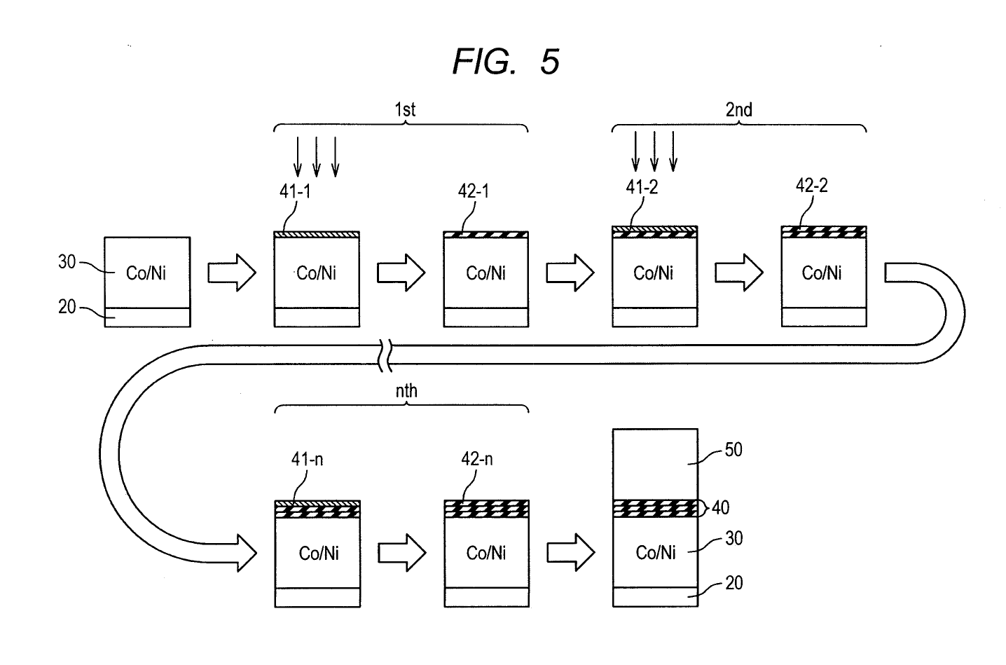

Hereinafter, a method for manufacturing the MTJ film 1 according to the embodiment is described in detail. FIG. 5 shows the method for manufacturing the MTJ film 1 according to the embodiment.

First, the underlayer 20 is formed over the substrate 10 by the sputtering method. The underlayer 20 is formed by a material which can grow the first ferromagnetic layer 30 having high crystal orientation. The preferable underlayer 20 includes Ta/Pt, Co/Pt, NiFeB/Pt, NiFeZr/Pt and NiFeZr/Pt/CoPt. Subsequently, the first ferromagnetic layer 30 having high crystal orientation is formed over the underlayer 20 by the sputtering method. Preferably, a Co/Ni stacked film in which Co films and Ni films are alternately and repeatedly deposited by sputtering is formed as the first ferromagnetic layer 30. Such a Co/Ni stacked film is a microcrystalline film having a crystal structure of strong fcc (111) orientation, and a perpendicular magnetization film having perpendicular magnetic anisotropy.

Then, the tunnel barrier layer 40 is formed over the first ferromagnetic layer 30. As shown in FIG. 4, the tunnel barrier layer 40 may be formed over the first ferromagnetic layer 30 through the thin interface layer 35 (for example, an amorphous CoFeB layer). Even in this case, crystal orientation of the first ferromagnetic layer 30 may affect to formation of the tunnel barrier layer 40 through the interface layer 35.

According to the embodiment, the tunnel barrier layer 40 is formed by the “multi-step oxidation method”. In other words, the tunnel barrier layer 40 is formed by repeating unit film formation treatment n times (n is an integer of 2 or more). Each unit film formation treatment includes an Mg deposition step and an oxidation step. The oxidation step is successively performed after the Mg deposition step.

An Mg film 41 is deposited by the sputtering method in the Mg deposition step. In FIG. 5, the Mg film deposited in an i-th Mg deposition step (i=1 to n) is represented as the Mg film 41-i.

The Mg film 41 deposited by the Mg deposition step is oxidized in the oxidation step. As a result, the MgO film 42 is formed. In FIG. 5, an MgO film obtained by an i-th (i=1 to n) oxidation step is represented as an MgO film 42-i. Here, the most preferable oxidation method is a “natural oxidation method” which is performed by introducing pure oxygen into vacuum. Alternatively, a “radical oxidation method” in which oxygen activated in a radical state is introduced into vacuum may be used.

According to the embodiment, each unit film formation treatment is performed so as to suppress growth of crystal grains. Specifically, a film thickness of the deposited Mg film 41 in each Mg deposition step is set to a range in which the crystal grains do not grow. A preferable range of Mg film thickness in which the growth of the crystal grains is suppressed has been found by the inventors of the present invention through experiments. The experiments and the preferable range of Mg film thickness are described below. Generation of the locally thin part as shown in FIG. 2 is prevented because the growth of the crystal grains is suppressed. As a result, deterioration of the readout properties such as the R×A and the MR ratio is prevented.

After completion of formation of the tunnel barrier layer 40, the second ferromagnetic layer 50 is formed over the tunnel barrier layer 50. The second ferromagnetic layer 50 includes any of Co, Ni and Fe or an alloy thereof. For example, a Co/Pt stacked film in which Co films and Pt films are alternately and repeatedly deposited by sputtering is formed as the second ferromagnetic layer 50. The second ferromagnetic layer 50 may also have a stacked ferrimagnetic structure.

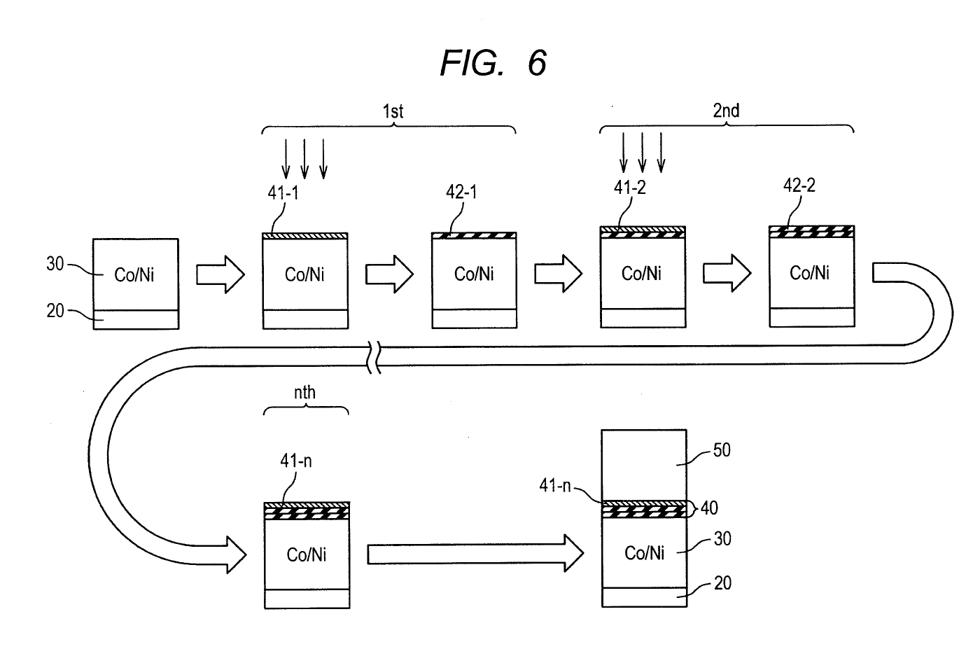

FIG. 6 shows a modification. In the modification, the oxidation step in the final (the n-th) unit film formation treatment is omitted. In other words, formation of the tunnel barrier layer 40 is completed, after the Mg film 41-n is formed by the n-th Mg deposition step. In this case, the second ferromagnetic layer 50 is formed over the Mg film 41-n. This is preferable because contact of the second ferromagnetic layer 50 to oxygen can be prevented.

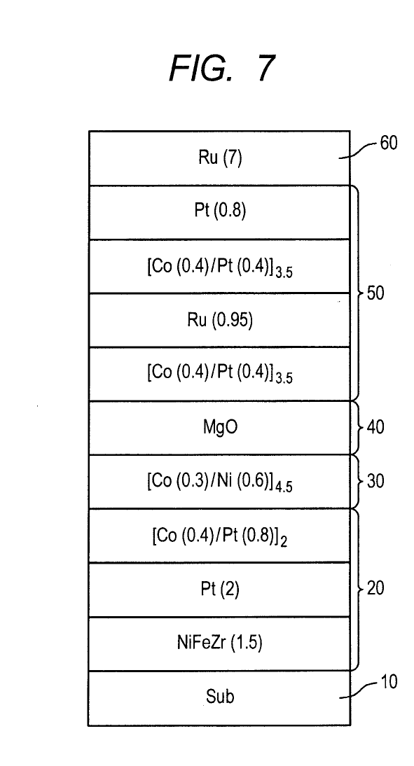

The steps shown in FIG. 6 and FIG. 7 are continuously performed in a vacuum chamber without open to the atmosphere in the middle of the steps.

### 3. Experiments and Preferable Range of Mg Film Thickness

The inventors of the present invention have found the preferable range of Mg film thickness in which the growth of the crystal grains is suppressed through the experiments. Hereinafter, the experiments and the preferable range of Mg film thickness are described.

FIG. 7 shows a sample film configuration used in the experiments. The underlayer 20 is a stacked layer of NiFeZr (1.5 nm), Pt (2 nm), Co (0.4 nm), Pt (0.8 nm), Co (0.4 nm) and Pt (0.8 nm). The first ferromagnetic layer 30 is a stacked film of Co (0.3 nm), Ni (0.6 nm), Co (0.3 nm), Ni (0.6 nm), Co (0.3 nm), Ni (0.6 nm), Co (0.3 nm), Ni (0.6 nm) and Co (0.3 nm). The tunnel barrier layer 40 is described separately.

The second ferromagnetic layer is a stacked ferrimagnetic film of Co (0.4 nm), Pt (0.4 nm), Co (0.4 nm), Pt (0.4 nm), Co (0.4 nm), Pt (0.4 nm), Co (0.4 nm), Ru (0.95 nm), Co (0.4 nm), Pt (0.4 nm), Co (0.4 nm), Pt (0.4 nm), Co (0.4 nm), Pt (0.4 nm), Co (0.4 nm) and Pt (0.8 nm). The cap layer 60 is an Ru layer (7 nm).

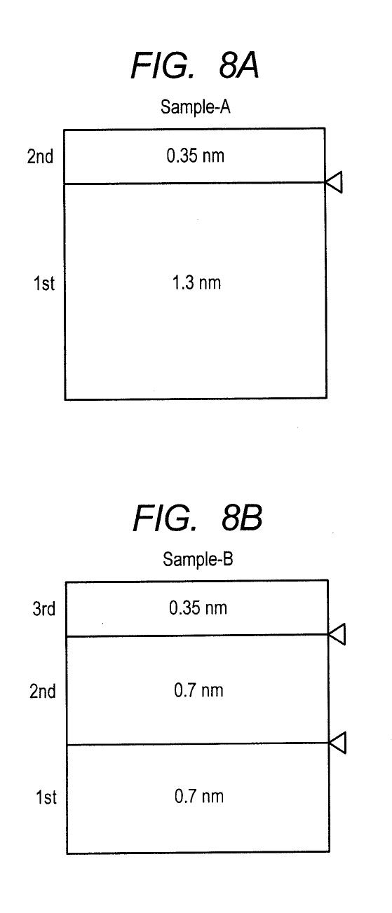

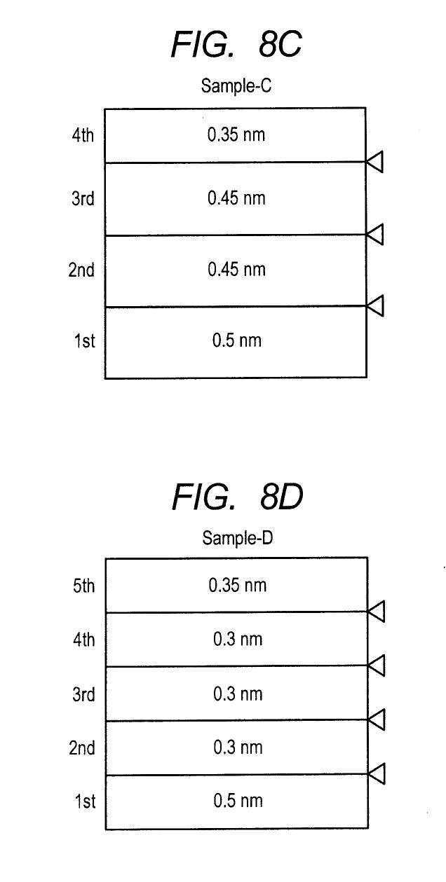

The tunnel barrier layer is an MgO film formed by the multi-step oxidation method. Here, four types of samples (Sample A, Sample B, Sample C and Sample D) are formed in different Mg film thickness conditions. FIG. 8A, FIG. 8B, FIG. 8C and FIG. 8D show the Mg film thickness conditions of Sample A, Sample B, Sample C and Sample D, respectively. The film thicknesses of Mg films 41 deposited in each Mg deposition step are shown in each view. Triangular marks represent performance of the oxidation steps. In this experiment, the modification shown in FIG. 6 is employed. The oxidation step in the final (the n-th) unit film formation treatment is omitted.

With reference to FIG. 8A, a method for forming the tunnel barrier layer 40 of Sample A is described. The first Mg deposition step was performed to deposit an Mg film 41-1 (1.3 nm). Subsequently, the first oxidation step was performed by the radical oxidation method. Finally, the second Mg deposition step was performed to deposit an Mg film 41-2 (0.35 nm).

With reference to FIG. 8B, a method for forming the tunnel barrier layer 40 of Sample B is described. The first Mg deposition step was performed to deposit an Mg film 41-1 (0.7 nm). Subsequently, the first oxidation step was performed by the radical oxidation method. Then, the second Mg deposition step was performed to deposit an Mg film 41-2 (0.7 nm). Subsequently, the second oxidation step was performed by the radical oxidation method. Finally, the third Mg deposition step was performed to deposit an Mg film 41-3 (0.35 nm). It should be noted that the Mg film thickness conditions of Sample B satisfy the film thickness conditions described in Japanese Unexamined Patent Application Publication No. 2000-357829.

With reference to FIG. 8C, a method for forming the tunnel barrier layer 40 of Sample C is described. The first Mg deposition step was performed to deposit an Mg film 41-1 (0.5 nm). Subsequently, the first oxidation step was performed by the radical oxidation method. Then, the second Mg deposition step was performed to deposit an Mg film 41-2 (0.45 nm). Subsequently, the second oxidation step was performed by the radical oxidation method. Then, the third Mg deposition step was performed to deposit an Mg film 41-3 (0.45 nm). Subsequently, the third oxidation step was performed by the radical oxidation method. Finally, the fourth Mg deposition step was performed to deposit an Mg film 41-4 (0.35 nm).

With reference to FIG. 8D, a method for forming the tunnel barrier layer 40 of Sample D is described. The first Mg deposition step was performed to deposit an Mg film 41-1 (0.5 nm). Subsequently, the first oxidation step was performed by the radical oxidation method. Then, the second Mg deposition step was performed to deposit an Mg film 41-2 (0.3 nm). Subsequently, the second oxidation step was performed by the radical oxidation method. Then, the third Mg deposition step was performed to deposit an Mg film 41-3 (0.3 nm). Subsequently, the third oxidation step was performed by the radical oxidation method. Then, the fourth Mg deposition step was performed to deposit an Mg film 41-4 (0.3 nm). Subsequently, the fourth oxidation step was performed by the radical oxidation method. Finally, the fifth Mg deposition step was performed to deposit an Mg film 41-5 (0.35 nm).

Multiple samples which vary oxidation time for every sample of each type were prepared in order to enable property comparison in optimum oxidation time conditions. Heat treatment (annealing) was applied to each prepared sample and the R×A and the MR ratio were measured. The R×A and the MR ratio were determined by a CIPT method.

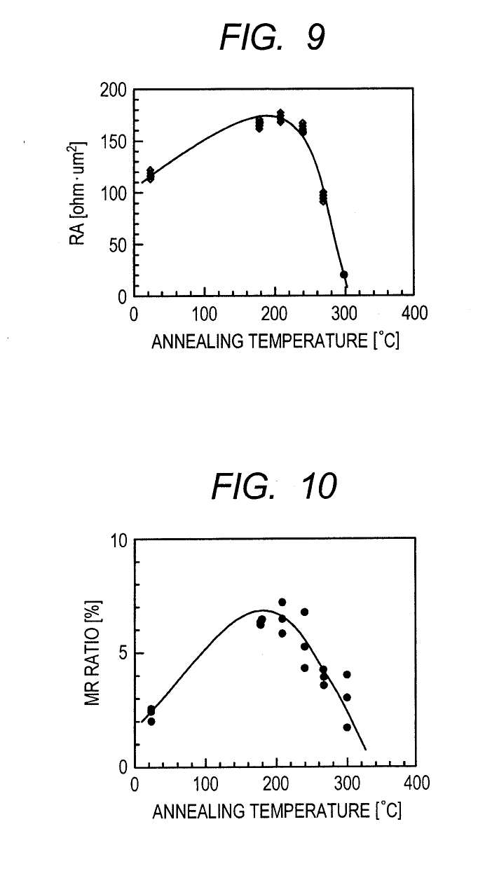

FIG. 9 shows annealing temperature dependence of R×As of Sample A. FIG. 10 shows annealing temperature dependence of MR ratios of Sample A. It is found that extreme decrease in R×A and decrease in the MR ratio are generated when heat treatment at a high temperature of 300° C. or more is performed. The problem was not solved by varying the oxidation time. As described in FIG. 2, a part locally having thin film thickness generated by growth of crystal grains probably becomes a leak spot, and this causes junction short circuit (decrease in the R×A) and decrease in the MR ratio. Heat resistance of the MTJ film deteriorates because the R×A and the MR ratio are decreased by heat treatment.

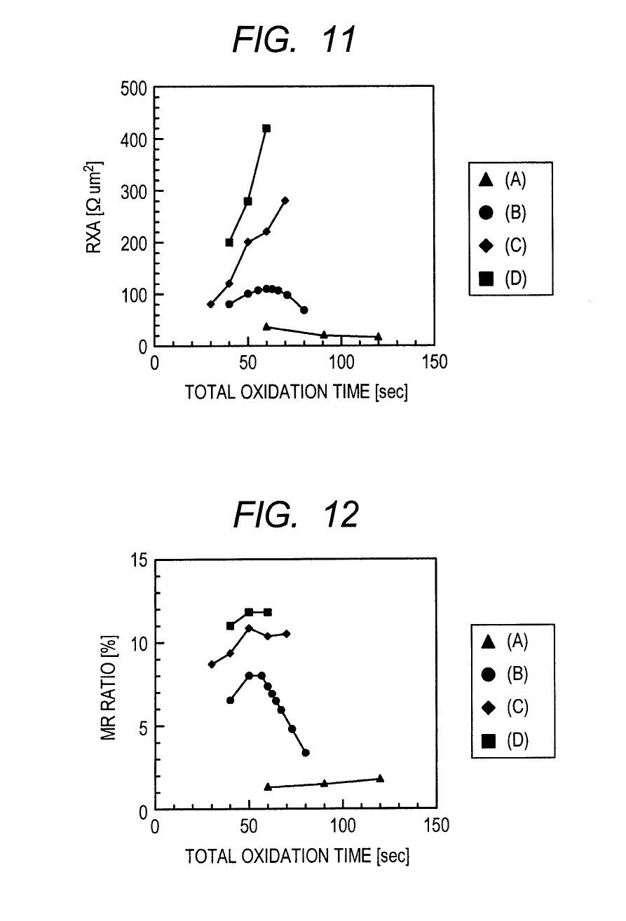

FIG. 11 is a graph showing oxidation time dependence of R×As of each sample. FIG. 12 is a graph showing oxidation time dependence of MR ratios of each sample. The horizontal axis represents the total of oxidation time in each oxidation step. In the graphs, triangle, circle, rhombus and square represent properties of Sample A, Sample B, Sample C and Sample D, respectively. Properties after the heat treatment at 300° C. are shown for Sample A, while properties after the heat treatment at 350° C. are shown for other Samples B, C and D.

It is found that the MR ratios for Samples B, C and D depend on oxidation time from FIG. 12. Particularly, every MR ratio is highest when the oxidation time is about 50 seconds. When the oxidation time is about 50 seconds, the MR ratios of Samples B, C and D are about 7.5%, 11% and 12%, respectively. On the other hand, it is confirmed that an MR ratio which is originally obtained is 11% to 12%, from an experiment in which a tunnel barrier layer is formed by the RF sputtering method using an MgO (oxide) target. Therefore, it is found that the problem of decrease in the MR ratio is solved for Sample C and Sample D. However, the problem is not sufficiently solved because an MR ratio of Sample B is clearly lower than MR ratios of Samples c and D. In addition, the problem is noticeable because the MR ratio of Sample A is extremely low as shown in FIG. 10.

From FIG. 11, it is found that the R×A varies depending on the oxidation time of Samples B, C and D. On the contrary, the R×A for Sample A is extremely low, not depending on the oxidation time. This means generation of junction short circuit. It is found that the R×A monotonically increases with increase in the oxidation time for Sample C and Sample D. The R×A at the optimum oxidation time (50 seconds) when the highest MR ratio is obtained is about 200 Ωμm² for Sample C and 300 Ωμm² for Sample D, and these values are sufficiently high. In other words, it is found that junction short circuit is not generated in Sample C and Sample D, and as a result, the problem of decrease in the R×A can be solved. The monotonic increase in the R×A with increase in the oxidation time can be explained as follows. That is, Mg which is not oxidized remains when the oxidation time is shorter than the optimum oxidation time, and thereby the R×A is decreased. When the oxidation time is longer than the optimum oxidation time, the R×A is increased by oxidation of a magnetic layer. Such monotonic increase in the R×A with increase in the oxidation time is a phenomenon which is generally seen in the case of the post-oxidation method.

Although a state of junction short circuit can probably be avoided in Sample B, its oxidation time dependence of the R×A is extremely anomalous. Specifically, when the oxidation time exceeds the optimum oxidation time, the R×A is decreased with increase in the oxidation time. This phenomenon is difficult to explain, and Sample B has high possibility that the problem of heat resistance deterioration for the R×A cannot be solved completely.

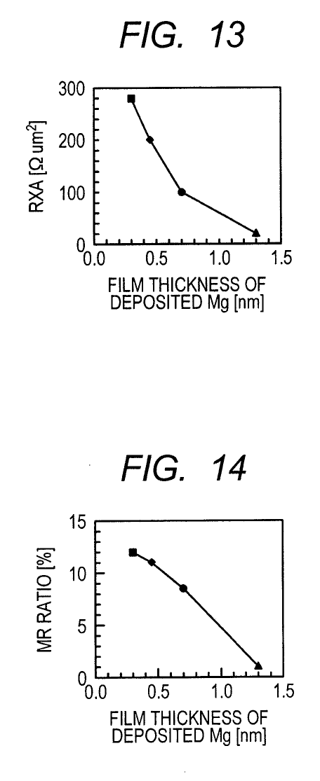

FIG. 13 is a graph showing Mg film thickness dependence of the R×A of each sample. FIG. 14 is a graph showing Mg film thickness dependence of the MR ratio of each sample. The horizontal axis represents the Mg film thickness in the Mg deposition step. More specifically, the Mg film thickness of 1.3 nm in the first Mg deposition step is employed for. Sample A. The Mg film thickness of 0.7 nm in the first and second Mg deposition steps is employed for Sample B. The Mg film thickness of 0.45 nm in the second and third Mg deposition steps is employed for Sample C. The Mg film thickness of 0.3 nm in the second to fourth Mg deposition steps is employed for Sample D. Vertical axis shows properties (the R×A and the MR ratio) at the optimum oxidation time when the highest MT ratio is obtained.

From FIG. 13 and FIG. 14, it is found that a thinner film thickness of deposited Mg provides better properties. This is because growth of crystal grains is suppressed when the film thickness of deposited Mg is thin. From the comparison between Sample C and Sample D, Sample D has better properties, even though both Mg film thicknesses in the first Mg deposition step are the same 0.5 nm thickness. This result should be considered as follows. The result is caused by Mg film thickness difference in the second Mg deposition step or later (in the case of Sample C: 0.45 nm and in the case of Sample D: 0.3 nm). In other words, thinner Mg film thickness is also preferable in the second Mg deposition step and later. Crystal orientation of the lower Co/Ni stacked film is also influenced in the second Mg deposition step and later.

From the experimental results described above, it becomes clear that the problem of property deterioration is not solved for Samples A and B, while the problem of property deterioration is solved for Samples C and D. It can be said that an Mg thickness in the first Mg deposition step may be at least 0.5 nm or less and an Mg thickens in the second Mg deposition step or later may be at least 0.45 nm or less from Mg film thickness conditions of Sample C and D. An upper limit value of a film thickness range is large in Japanese Unexamined Patent Application Publication No. 2000-357829 because the problem of “properties deterioration by growth of crystal grains” is not recognized. It is said that the upper limit value of a film thickness range is preferably defined in the present invention from the viewpoint of “suppressing growth of crystal grains”. A lower limit value of an Mg film thickness range may be a similar value described in Japanese Unexamined Patent Application Publication No. 2000-357829. Therefore, a preferable Mg film thickness range is as follows.

An Mg film thickness range in the first Mg deposition step: 0.3 nm or more and 0.5 nm or less. An Mg film thickness range in the second Mg deposition step or later: 0.1 nm or more and 0.45 nm or less.

A film thickness of an MgO film 42 obtained by oxidizing the Mg film 41 is thinner than the original Mg film thickness. Theoretically, the film thickness of the MgO film 42 is 80.5% of the film thickness of the Mg film 41. Therefore, a preferable film thickness range of the first layer of an MgO film 42-1 (the closest MgO film to the first ferromagnetic layer 30) is theoretically 0.2415 nm or more and 0.4025 nm or less. A preferable film thickness range of the second layer or later of MgO film 42-j (j=2-n) is theoretically 0.0805 nm or more and 0.36225 nm or less.

As described above, the embodiments are described with reference to the accompanying drawings. However, the present invention is not limited to the above-described embodiments, and can be modified by those skilled in the art within a range not depart from the scope.

What is claimed is:

1. A method for manufacturing an MTJ film, the method comprising the steps of:
forming a first ferromagnetic layer;
forming a tunnel barrier layer over the first ferromagnetic layer; and
forming a second ferromagnetic layer over the tunnel barrier layer,
wherein the first ferromagnetic layer is a Co/Ni stacked film having perpendicular magnetic anisotropy, and
wherein the step for forming a tunnel barrier layer comprises repeating unit film formation treatment n times (n is an integer of 2 or more), and
wherein the unit film formation treatment includes the steps of:
depositing an Mg film by a sputtering method; and
oxidizing the deposited Mg film, and
wherein a film thickness of the deposited Mg film in the first unit film formation treatment is 0.3 nm or more and 0.5 nm or less; and
wherein a film thickness of the deposited Mg film in the second unit film formation treatment or later is 0.1 nm or more and 0.45 nm or less.

2. The method for manufacturing the MTJ film according to claim 1,
wherein the step of oxidizing the deposited Mg film in the n-th unit film formation treatment is omitted.

3. The method for manufacturing the MTJ film according to claim 1,
wherein the step of oxidizing the deposited Mg film is performed by a natural oxidation.

4. The method for manufacturing the MTJ film according to claim 1,
wherein the tunnel barrier layer is formed over the first ferromagnetic layer through an amorphous CoFeB layer.

5. The method for manufacturing the MTJ film according to claim 1,
wherein the first ferromagnetic layer is formed over a underlayer; and
wherein the underlayer is made of any one of Ta/Pt, Co/Pt, NiFeB/Pt, NiFeZr/Pt and NiFeZr/Pt/CoPt.

6. A method for manufacturing an MTJ film, the method comprising the steps of:
forming a first ferromagnetic layer;
forming a tunnel barrier layer over the first ferromagnetic layer; and
forming a second ferromagnetic layer over the tunnel barrier layer;
wherein the first ferromagnetic layer has a crystal structure having fcc (ill) orientation, and
wherein the step for forming the tunnel barrier layer comprises repeating unit film formation treatment n times (n is an integer of 2 or more), and
wherein the unit film formation treatment includes the steps of:
depositing an Mg film by a sputtering method; and
oxidizing the deposited Mg film, and
wherein a film thickness of the deposited Mg film in the first unit film formation treatment is 0.3 nm or more and 0.5 nm or less, and
wherein a film thickness of the deposited Mg film in the second unit film formation treatment or later is 0.1 nm or more and 0.45 nm or less.

7. An MTJ film comprising:
a first ferromagnetic layer;
a tunnel barrier layer formed over the first ferromagnetic layer; and
a second ferromagnetic layer formed over the tunnel barrier layer,
wherein the first ferromagnetic layer is a Co/Ni stacked film having perpendicular magnetic anisotropy, and
wherein the tunnel barrier layer includes n layers (n is an integer of 2 or more) of MgO films, and
wherein a film thickness of a first MgO film closest to the first ferromagnetic layer among the n layers of MgO films is 0.2415 nm or more and 0.4025 nm or less, and
wherein each film thickness of the n layers of MgO films except the first MgO film is 0.0805 nm or more and 0.36225 nm or less.
